(19) United States
(12) Patent Application Publication
(10) Pub. No.: US 2026/0304927 A1
(43) Pub. Date: Oct. 1, 2026

(54) SEMICONDUCTOR DEVICES WITH GATE CUT STRUCTURES INTEGRATED WITH FIN CUT STRUCTURES

(71) Applicant: Intel Corporation, Santa Clara, CA (US)

(72) Inventors: Sheng-Po Fang, Vancouver, WA (US); Hwichan Jun, Portland, OR (US); Guillaume Bouche, Portland, OR (US)

(73) Assignee: Intel Corporation, Santa Clara, CA (US)

(21) Appl. No.: 19/092,426

(22) Filed: Mar. 27, 2025

(51) Int. Cl. H10D 84/83; H10D 30/00; H10D 30/01; H10D 30/43; H10D 30/47; H10D 62/10; H10D 84/01

(52) U.S. Cl. CPC H10D 84/832; H10D 30/017; H10D 30/0191; H10D 30/47; H10D 30/502; H10D 62/121; H10D 84/0151; H10D 84/83125; H10D 30/014; H10D 30/43

(57) ABSTRACT

Techniques are provided herein to form an integrated circuit having one or more gate cuts that are integrated (e.g., having the same dielectric material) with one or more fin cut structures. According to some such examples, a portion of an integrated circuit may include two transistors with one transistor being an n-channel device with the other being a p-channel device. The transistors may be configured, for instance, as an inverter or other functional circuit. Gate cut structures and fin cut structures are formed around the transistors to isolate the devices from other adjacent devices formed on the die. A same dielectric material may be deposited and polished to complete the formation of both the gate cut structures and the fin cut structures at the same time. The reduction in the number of polishing steps facilitates the formation of smaller gate heights for further cost and area saving.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, fabrication processes used to pattern or polish structures across the die can have an effect on later processes, which requires careful planning for all fabrication processes used. Accordingly, there remain a number of non-trivial challenges with respect to forming semiconductor devices.

### BRIEF DESCRIPTION OF THE DRAWINGS

FIG. 1A is a plan view of an example layout of a portion of an integrated circuit having integrated gate cuts and fin cut structures around semiconductor devices, in accordance with an embodiment of the present disclosure.

FIG. 1B is a cross-section view of the layout from FIG. 1A showing merged dielectric material between a fin cut structure and gate cuts, in accordance with an embodiment of the present disclosure.

FIGS. 2A and 2B are plan and cross-sectional views that illustrate one stage in an example process for forming an integrated circuit with merged dielectric material between a fin cut structure and gate cuts, in accordance with an embodiment of the present disclosure.

FIGS. 3A and 3B are plan and cross-sectional views that illustrate another stage in the example process for forming an integrated circuit with merged dielectric material between a fin cut structure and gate cuts, in accordance with an embodiment of the present disclosure.

FIGS. 4A and 4B are plan and cross-sectional views that illustrate another stage in the example process for forming an integrated circuit with merged dielectric material between a fin cut structure and gate cuts, in accordance with an embodiment of the present disclosure.

FIGS. 5A and 5B are plan and cross-sectional views that illustrate another stage in the example process for forming an integrated circuit with merged dielectric material between a fin cut structure and gate cuts, in accordance with an embodiment of the present disclosure.

FIGS. 6A and 6B are plan and cross-sectional views that illustrate another stage in the example process for forming an integrated circuit with merged dielectric material between a fin cut structure and gate cuts, in accordance with an embodiment of the present disclosure.

FIGS. 7A and 7B are plan and cross-sectional views that illustrate another stage in the example process for forming an integrated circuit with merged dielectric material between a fin cut structure and gate cuts, in accordance with an embodiment of the present disclosure.

FIGS. 8A and 8B are plan and cross-sectional views that illustrate another stage in the example process for forming an integrated circuit with merged dielectric material between a fin cut structure and gate cuts, in accordance with an embodiment of the present disclosure.

FIGS. 9A and 9B are plan and cross-sectional views that illustrate another stage in the example process for forming an integrated circuit with merged dielectric material between a fin cut structure and gate cuts, in accordance with an embodiment of the present disclosure.

FIGS. 10A and 10B are plan and cross-sectional views that illustrate another stage in the example process for forming an integrated circuit with merged dielectric material between a fin cut structure and gate cuts, in accordance with an embodiment of the present disclosure.

FIGS. 11A and 11B are plan and cross-sectional views that illustrate another stage in the example process for forming an integrated circuit with merged dielectric material between a fin cut structure and gate cuts, in accordance with an embodiment of the present disclosure.

FIGS. 12A and 12B are plan and cross-sectional views that illustrate another stage in the example process for forming an integrated circuit with merged dielectric material between a fin cut structure and gate cuts, in accordance with an embodiment of the present disclosure.

FIGS. 13A and 13B are plan and cross-sectional views that illustrate another stage in the example process for forming an integrated circuit with merged dielectric material between a fin cut structure and gate cuts, in accordance with an embodiment of the present disclosure.

FIGS. 14A and 14B are plan and cross-sectional views that illustrate another stage in the example process for forming an integrated circuit with merged dielectric material between a fin cut structure and gate cuts, in accordance with an embodiment of the present disclosure.

FIG. 15 illustrates a cross-sectional view of a chip package containing one or more semiconductor dies, in accordance with some embodiments of the present disclosure.

FIG. 16 is a flowchart of a fabrication process for semiconductor devices that have merged dielectric material between a fin cut structure and gate cuts, in accordance with an embodiment of the present disclosure.

FIG. 17 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having one or more gate cuts that are integrated (e.g., having the same dielectric material) with one or more fin cut structures. According to some such examples, a portion of an integrated circuit may include two transistors with one transistor being an n-channel device with the other being a p-channel device. The transistors may be configured, for instance, as an inverter or other functional circuit. The techniques can be used in any number of transistor technologies, but are particularly useful in finFET transistors, gate-all-around (GAA) (e.g., nanoribbon) transistor configurations or forksheet transistor configurations. According, to some embodiments, gate cut structures and fin cut structures are formed around the transistors to isolate the devices from other adjacent devices formed on the die. A same dielectric material may be deposited and polished to complete the formation of both the gate cut structures and the fin cut structures at the same time. The reduction in the number of polishing steps facilitates the formation of smaller gate heights for further cost and area saving. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Several processes used to fabricate certain structures can impose limitations on the dimensions of other structures. For example, polishing steps using for example, chemical mechanical polishing (CMP), are commonly employed to polish back over-filled dielectric or other material. Reducing the number of polishing steps can be helpful when trying to form small structures, since polishing is a non-selective process that is highly likely to remove some portion of all structures across the substrate. Gate cuts and fin cut structures are dielectric structures that are formed to isolate semiconductor devices from other adjacent devices along the gate direction (in the case of gate cuts) and along the fin direction (in the case of fin cut structures). Polishing operations are used during the formation of both gate cuts and fin cut structures, which can limit how small other structures can be made, such as the gate structures. For example, for a larger number of front-end-of-the-line (FEOL) polishings, the initial dummy gate height is made taller to accommodate material loss at each polishing step. In turn, any increase in aspect ratio results in increased challenge at each step and costlier processes with higher variability, jeopardizing yield. It may be desirable to reduce the number of polishing steps to respectively reduce the initial dummy gate height.

Thus, and in accordance with an embodiment of the present disclosure, techniques are provided herein to form gate cuts and fin cut structures with a merged dielectric material that uses fewer polishing steps compared to traditional fabrication processes. According to some embodiments, a portion of an integrated circuit includes a first semiconductor device having a first semiconductor region extending lengthwise in a first direction between first source or drain regions and a second semiconductor device having a second semiconductor region extending lengthwise in the first direction (e.g., parallel to the first semiconductor region) between second source or drain regions. A gate structure extends in a second direction substantially orthogonal to the first direction across both the first and second semiconductor regions. One or more gate cuts may be provided that extend along the first direction across the gate structure and through an entire thickness of the gate structure. One or more fin cut structures may be provided that extend along the second direction (e.g., parallel with the gate structure) within another gate trench adjacent to the gate structure. According to some embodiments, a same continuous dielectric material extends between both the one or more gate cuts and the one or more fin cut structures. In this manner, a continuous body of dielectric material, with no seams between gate cut portions and fin cut portions, may substantially fill the one or more gate cuts and the one or more fin cut structures. A sacrificial material may be used as a placeholder while forming the one or more gate cuts. A portion of the sacrificial material may be removed while forming a trench that extends along the second direction to interest the sacrificial material. After removing the sacrificial material, a dielectric material may be formed within the trench and the region previously occupied by the sacrificial material at the same time. The entire merged dielectric structure can be polished using a single CMP operation.

According to an embodiment, an integrated circuit includes a semiconductor region extending from a source or drain region in a first direction, a gate structure extending over the semiconductor region in a second direction substantially orthogonal to the first direction, a first dielectric structure extending along the first direction and crossing the gate structure such that the first dielectric structure extends through at least an entire thickness of the gate structure, and a second dielectric structure extending along the second direction parallel to the gate structure and intersecting the first dielectric structure. The first dielectric structure and the second dielectric structure share a same continuous dielectric material. In some such example cases, the first dielectric structure and the second dielectric are occupied by a continuous body of dielectric material, without seams between the first and second dielectric structures. In still other such example cases, there may be a continuous liner or barrier layer that extends continuously along the edges making up the first and second dielectric structures, and a continuous body of dielectric material occupies the remaining portions of the first and second dielectric structures.

According to another embodiment, an electronic device includes a chip package having one or more dies. At least one of the one or more dies includes a semiconductor device having a semiconductor region extending from a source or drain region in a first direction, and a gate structure extending over the semiconductor region in a second direction substantially orthogonal to the first direction, a first dielectric structure extending along the first direction and crossing the gate structure such that the first dielectric structure extends through at least an entire thickness of the gate structure, a second dielectric structure extending along the first direction and crossing the gate structure such that the second dielectric structure extends through at least an entire thickness of the gate structure, and a third dielectric structure extending along the second direction parallel to the gate structure and intersecting the first dielectric structure and the second dielectric structure. The first dielectric structure, the second dielectric structure, and the third dielectric structure share a same continuous dielectric material. In this manner, a continuous body of dielectric material, with no seams between gate cut portions and fin cut portions, may substantially fill or otherwise occupy the first dielectric structure, the second dielectric structure, and the third dielectric structure (not counting any liner or barrier layer or the like, which may also be present within gate cut portions and fin cut portions).

According to another embodiment, an integrated circuit includes a semiconductor region extending from a first source or drain region in a first direction, a gate structure extending over the semiconductor region in a second direction substantially orthogonal to the first direction, and a dielectric structure. The dielectric structure has a first section that extends along the first direction and crosses the gate structure such that the first section of the dielectric structure extends through at least an entire thickness of the gate structure and has a second section that extends along the second direction parallel to the gate structure and intersects the first section of the dielectric structure. The dielectric structure comprises a dielectric material that seamlessly extends between the first section and the second section.

According to another embodiment, a method of forming an integrated circuit includes forming a fin comprising semiconductor material, the fin extending above a substrate and extending lengthwise in a first direction; forming a first sacrificial gate and a second sacrificial gate each extending in a second direction over the semiconductor material of the fin; forming spacer structures on sidewalls of the first and second sacrificial gates; etching through exposed portions of the fin not protected by the first and second sacrificial gates and spacer structures; forming source or drain regions at exposed ends of the fin; replacing the first sacrificial gate with a first gate structure and the second sacrificial gate with a second gate structure; etching a first trench recess extending in the first direction across both the first gate structure and the second gate structure and through an entire thickness of each of the first gate structure and the second gate structure; forming a sacrificial material within the first trench recess; etching a second trench recess extending in the second direction through the second gate structure and through an entire thickness of the second gate structure, wherein the second trench recess exposes at least a portion of the sacrificial material; removing the sacrificial material; and forming one or more dielectric materials in both the first trench recess and the second trench recess.

The techniques can be used with any type of non-planar transistors, including finFETs (sometimes called double-gate transistors, or tri-gate transistors), or nanowire and nanoribbon transistors (sometimes called gate-all-around transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the lack of an interface liner between gate cut structures and fin cut structures, such that there is a continuous dielectric material extending between or otherwise making up the gate cut structures and fin cut structures, not counting any liner or barrier layer of the like, which may also be present between walls of the gate/fin cut structures and the continuous dielectric material making up the bulk of the gate/fin cut structures, and which may run continuously from gate cut to fin cut to gate cut, and so on. Such tools may also indicate the lack of a seam through the middle of a majority of a height of the gate cut structures where they are intersected by the fin cut structures.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

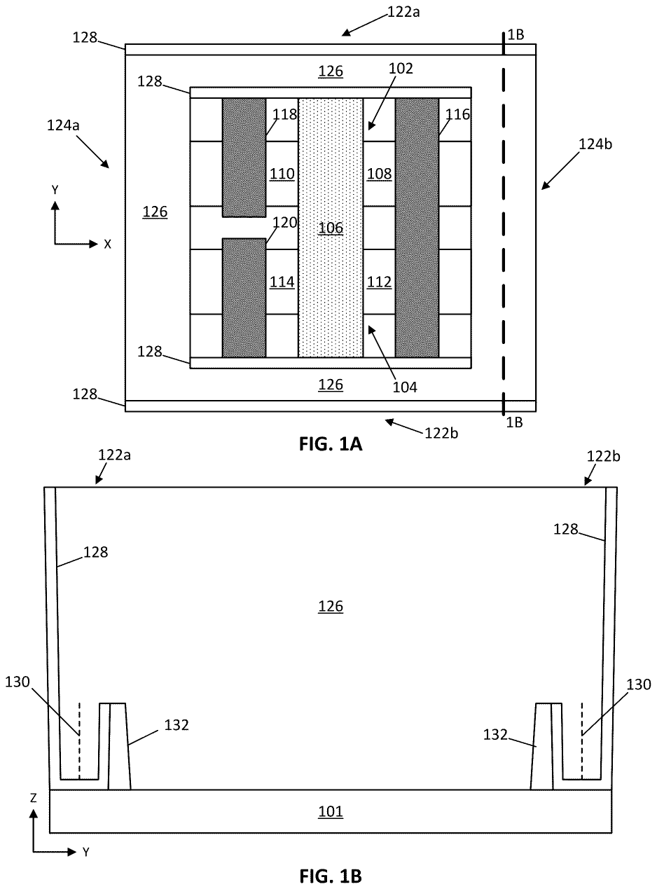

FIG. 1A is a plan layout view of a portion of an integrated circuit with merged gate cuts and fin cuts around devices, according to some embodiments. FIG. 1B illustrates a cross-section view taken through plane 1B-1B as seen in FIG. 1A. As shown, the integrated circuit includes a first semiconductor device 102 and a second semiconductor device 104 arranged in an inverter configuration. In some examples, the illustrated portion of the integrated circuit represents a standard unit cell that may be repeated across a die. The boundaries of the standard unit cell may be generally defined by the gate cuts and fin cuts. First semiconductor device 102 and second semiconductor device 104 share a gate structure 106 that extends along the second direction over the semiconductor regions of both first semiconductor device 102 and second semiconductor device 104. The semiconductor region of first semiconductor device 102 extends between a first source or drain region 108 and a second source or drain region 110 (e.g., beneath a portion of gate structure 106), and the semiconductor region of second semiconductor device 104 extends between a third source or drain region 112 and a fourth source or drain region 114 (e.g., beneath another portion of gate structure 106).

Each of semiconductor devices 102 and 104 may be, for example, non-planar metal oxide semiconductor (MOS) transistors, such as tri-gate (e.g., finFET) or gate-all-around (GAA) transistors, although other transistor topologies and types could also benefit from the techniques and structures provided herein. The semiconductor material used in each of the semiconductor devices may be formed from or on a semiconductor substrate 101. According to some embodiments, substrate 101 is removed following the completion of all topside processing and is replaced with one or more backside dielectric layers.

The one or more semiconductor regions of the devices may include fins that can be, for example, native to substrate 101 (formed from the substrate itself), such as silicon fins etched from a bulk silicon substrate. Alternatively, the fins can be formed of material deposited onto substrate 101. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

Gate structure 106 may include a gate electrode that is made up of a conductive fill and one or more metal workfunction layers, according to some embodiments. Gate structure 106 also includes a gate dielectric that may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. In some embodiments, first semiconductor device 102 is a n-channel device having a portion of gate structure 106 with one or more workfunction layers of titanium aluminum carbide. Other metal workfunction layers of n-channel devices can include tantalum nitride (TaN). In some embodiments, second semiconductor device 104 is a p-channel device having a portion of gate structure 106 with one or more workfunction layers of tungsten. Other metal workfunction layers of p-channel devices can include tantalum nitride (TaN) and titanium nitride (TiN).

The gate dielectric of gate structure 106 may include any suitable gate dielectric material(s). In some embodiments, the gate dielectric includes a layer of native oxide material (e.g., silicon dioxide germanium dioxide, or SiGe oxide) on the semiconductor regions (e.g., nanoribbons) of semiconductor devices 102 and 104, and a layer of high-k dielectric material (e.g., hafnium oxide or aluminum oxide) on the native oxide.

According to some embodiments, a first topside contact 116 extends along the second direction across the top surfaces of both first source or drain region 108 and third source or drain region 112, a second topside contact 118 extends along the second direction across the top surface of second source or drain region 110, and a third topside contact 120 extends along the second direction across the top surface of fourth source or drain region 114.

According to some embodiments, gate cuts 122a and 122b (collectively referred to as gate cuts 122) extend in the first direction across gate structure 106 and through at least an entire thickness of gate structure 106, and fin cuts 124a and 124b (collectively referred to as fin cuts 124) extend along the second direction parallel to gate structure 106 and between gate cuts 122a and 122b. In some embodiments, second topside contact 118 may contact at least a portion of the top surface of second source or drain region 110 and continue to extend along the second direction until it abuts against gate cut 122a. Similarly, third topside contact 120 may contact at least a portion of the top surface of fourth source or drain region 114 and continue to extend along the second direction until it abuts against gate cut 122b.

According to some embodiments, a same dielectric material 126 extends through gate cuts 122 and fin cuts 124. Dielectric material 126 may be any suitable dielectric, such as silicon dioxide or silicon oxynitride. Gate cuts 122 may also include a liner 128 that creates a barrier between dielectric material 126 and other transistor elements, such as gate structure 106. According to some embodiments, at least a portion of liner 128 is not present between gate cuts 122 and fin cuts 124, as seen in the cross-section of FIG. 1B. this allows for dielectric material 126 to seamlessly exist across both gate cuts 122 and fin cuts 124. In some examples, a bottom portion of gate cuts 122 remains intact with a portion of liner 128 being between a portion of dielectric material 126 in gate cuts 122 and dielectric material 126 of fin cuts 124, as illustrated more clearly in FIG. 1B. Liner 128 may be any suitable dielectric material having sufficient etch selectivity to dielectric material 126. In some examples, liner 128 includes silicon nitride. Liner 128 may have a thickness between about 1 nm and about 10 nm. In some embodiments, dielectric liner 128 includes a high-k material (e.g., a material having a dielectric constant of 5.0 or greater) and dielectric material 126 includes a low-k dielectric material (e.g., a material having a dielectric constant of 4.5 or less).

According to some embodiments, a seam 130 may be visible in the middle of the bottom portion of gate cuts 122 where they intersect with fin cuts 124. In some cases, seam 130 forms due to the process of forming dielectric material 126 on the walls of the bottom portions of gate cuts 122. As seen in FIG. 1B, there is no seam present along the majority of the height of gate cuts 122 where they intersect with fin cut 124b.

According to some embodiments, the fabrication process used to form the merged gate cuts 122 and fin cuts 124 may yield other structures, such as dielectric plugs 132 directly adjacent to the bottom portions of gate cuts 122. Accordingly, dielectric plugs 132 may be directly between the bottom portions of gate cuts 122a and 122b and fin cut 124b along the second direction, as seen in FIG. 1B. Dielectric plugs 132 may be any suitable dielectric material used as shallow trench isolation (STI) between devices, which may include silicon dioxide, silicon oxynitride, or silicon oxycarbonitride.

### Fabrication Methodology

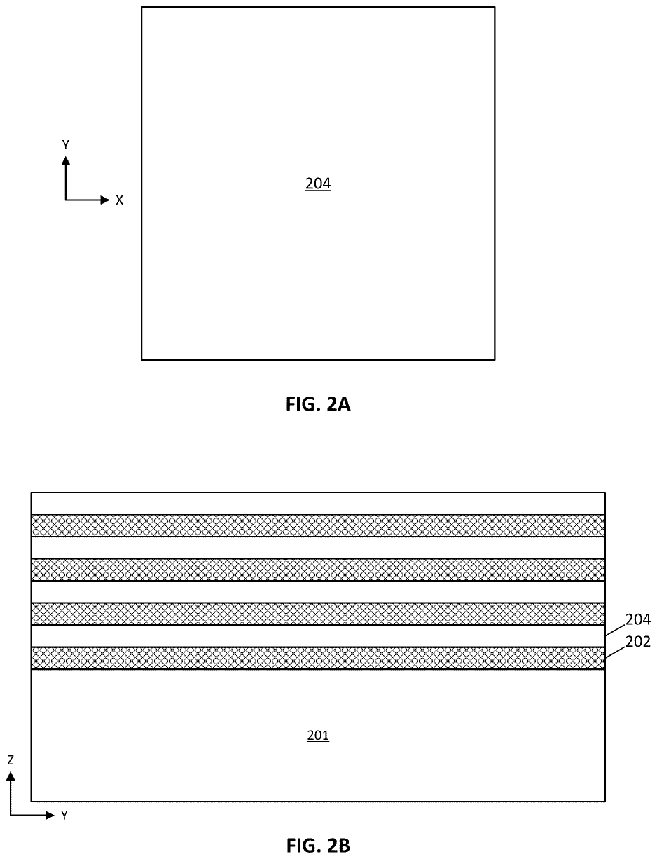

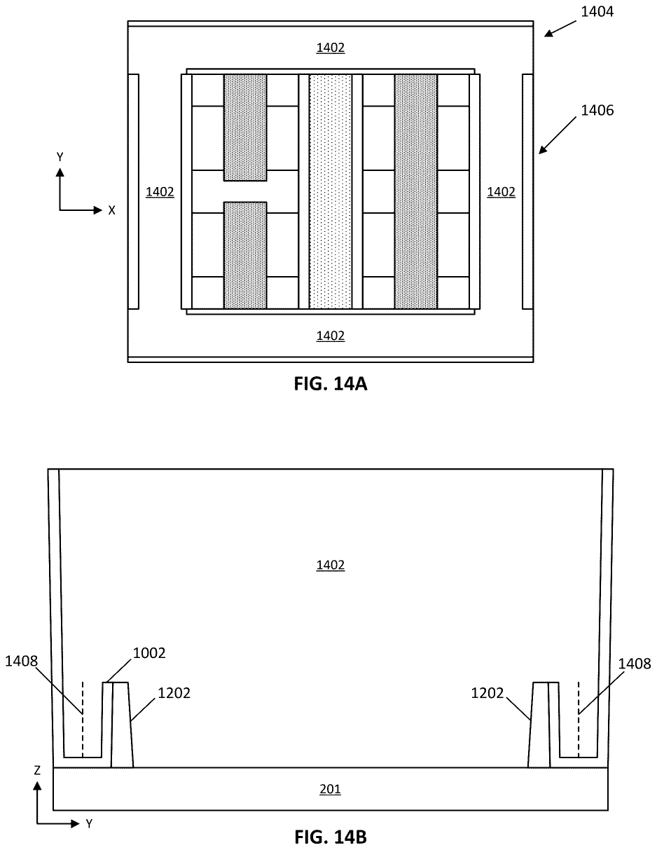

FIG. 2A-14A and 2B-14B include plan and cross-sectional views, respectively, that collectively illustrate an example process for forming a portion of an integrated circuit with merged gate cuts and fin cuts, in accordance with an embodiment of the present disclosure. FIG. 2A-14A represent a similar plan view as that of FIG. 1A, while FIG. 2B-14B represent the corresponding cross-section view similar to FIG. 1B along the 1B-1B plane. Each set of figures sharing the same letter shows an example structure that results from the process flow up to that point in time, so the depicted structure evolves as the process flow continues, culminating in the structure shown in FIGS. 14A and 14B, which is similar to the structure shown in FIGS. 1A and 1B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure.

FIGS. 2A and 2B illustrate plan and cross-section views taken through a substrate 201 having a series of material layers formed over the substrate, according to an embodiment of the present disclosure. Alternating material layers may be deposited over a substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 are silicon germanium (SiGe) while sacrificial layers 202 include a semiconductor material suitable for use as a nanoribbon such as silicon (Si), SiGe, germanium, or III-V materials like indium phosphide (InP) or gallium arsenide (GaAs). In examples where SiGe is used in each of semiconductor layers 204 and in sacrificial layers 202, the germanium concentration is different between semiconductor layers 204 and sacrificial layers 202. For example, semiconductor layers 204 may include a higher germanium content compared to sacrificial layers 202.

While dimensions can vary from one example embodiment to the next, the thickness of each semiconductor layer 204 may be between about 5 nm and about 20 nm. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any known material deposition technique, such as chemical vapor deposition (CVD), plasma-enhanced chemical vapor deposition (PECVD), physical vapor deposition (PVD), or atomic layer deposition (ALD), or epitaxial growth.

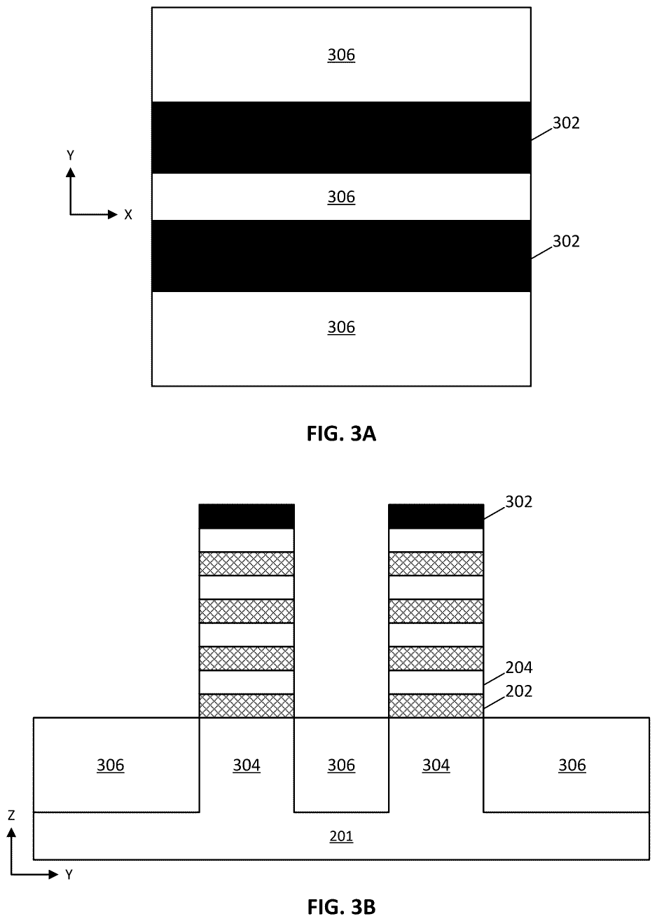

FIGS. 3A and 3B depict plan and cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows extending along a first direction (e.g., along the X-axis as shown in FIG. 3A) to form corresponding rows of fins from the alternating layer stack of sacrificial layers 202 and semiconductor layers 204.

According to some embodiments, an anisotropic etching process using, for example, reactive ion etching (RIE) through the layer stack continues into at least a portion of substrate 201. Portions of substrate 201 beneath the fins are not etched and yield subfin regions 304. The etched portion of substrate 201 may be filled with a dielectric material to from a dielectric layer 306 that acts as shallow trench isolation (STI) between adjacent fins, as seen in FIG. 3B. Dielectric layer 306 may include any dielectric material such as silicon dioxide. Subfin regions 304 represent remaining portions of substrate 201 between dielectric layer 306, according to some embodiments.

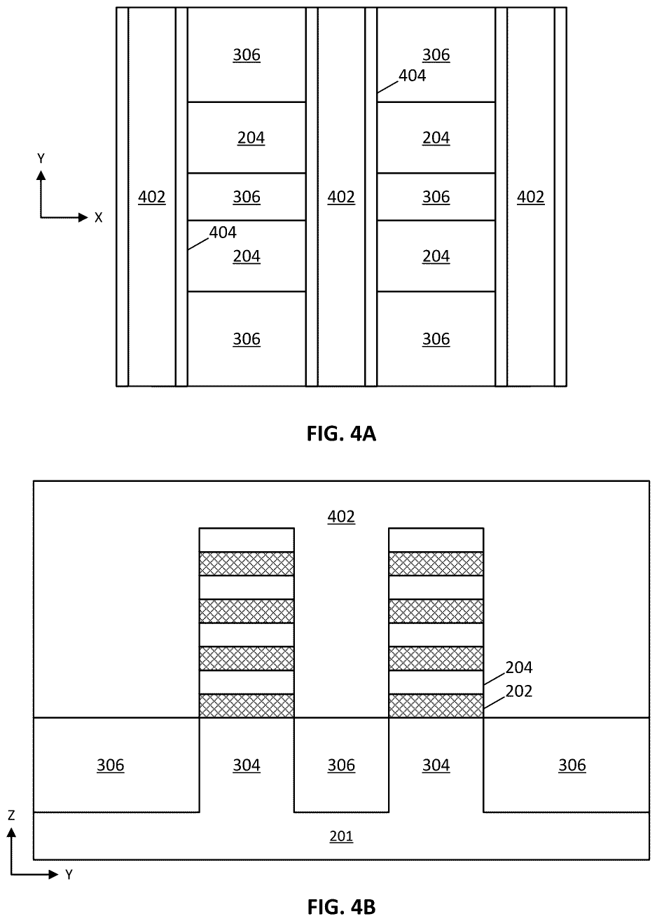

FIGS. 4A and 4B depict plan and cross-section views of the structure shown in FIGS. 3A and 3B following the formation of sacrificial gates 402 and spacer structures 404, according to some embodiments. A gate masking layer may first be patterned in strips that extend orthogonally across each of the fins in a second direction (e.g., along the Y-axis as shown in FIG. 4A) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gates 402 may be any material that can be selectively removed without damaging the semiconductor material of the fins. In some examples, sacrificial gates 402 includes polysilicon.

According to some embodiments, spacer structures 404 (also referred to as gate spacers or upper gate spacers) are formed along the sidewalls of sacrificial gates 402. Spacer structures 404 may be deposited and then etched back such that they remain mostly only on sidewalls of any exposed structures. According to some embodiments, spacer structures 404 may be any suitable dielectric material, such as silicon nitride, silicon carbon nitride, or silicon oxycarbonitride.

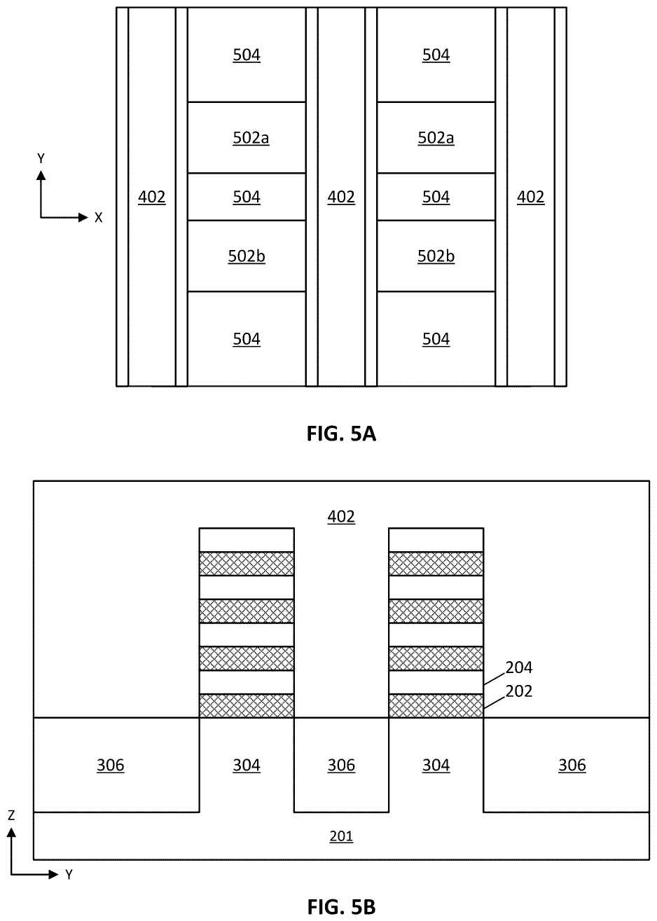

FIGS. 5A and 5B depict plan and cross-section views of the structure shown in FIGS. 4A and 4B following the removal of exposed portions of the fins not protected by sacrificial gates 402 (and spacer structures 404) and subsequent formation of source or drain regions, according to some embodiments. The exposed fin portions may be removed using any anisotropic etching process, such as RIE. The removal of the exposed fin portions creates source or drain trenches that alternate with gate trenches (currently filled with sacrificial gates 402) along the first direction, according to some embodiments. At least a portion of subfin regions 304 may be removed during the etching process.

According to some embodiments, each of source or drain regions 502a and 502b may be formed in the areas that had been previously occupied by the exposed fins within the source/drain trenches. According to some embodiments, the source or drain regions are epitaxially grown from the exposed semiconductor material at the ends of the semiconductor layers beneath the sacrificial gates 402. In some example embodiments, source or drain regions 502a are p-type source or drain regions (e.g., epitaxial silicon germanium) while source or drain regions 502b are n-type source or drain regions (e.g., epitaxial silicon), or vice versa. Accordingly, source or drain regions of one dopant type may be formed first before the formation of source or drain regions of the other dopant type.

According to some embodiments, a dielectric fill 504 is provided between adjacent source or drain regions along the source/drain trench. In some examples, dielectric fill 504 occupies a remaining volume within the source/drain trench around and over each of source or drain regions 502a and 502b. Dielectric fill 504 may be any dielectric material, such as silicon dioxide. In some examples, dielectric fill 504 extends up to and planar with a top surface of sacrificial gate 402 (e.g., following a polishing procedure). A planarization process such as chemical mechanical polish (CMP) can be used to remove any excess dielectric fill 504 and planarize the structure. Dielectric fill 504 is not illustrated over the source or drain regions 502a/502b in the plan view of FIG. 5A for clarity.

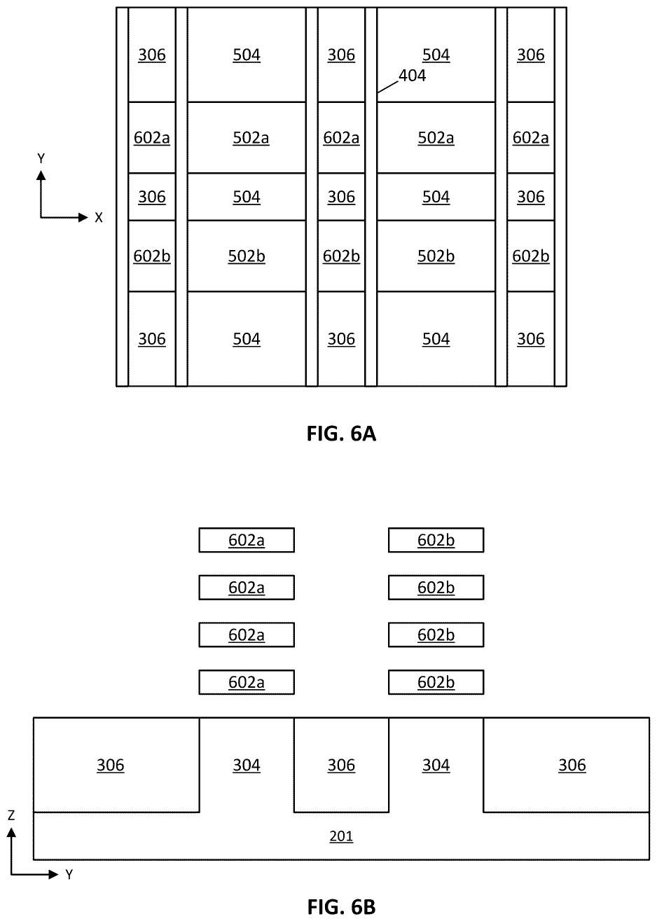

FIGS. 6A and 6B depict plan and cross-section views of the structure shown in FIGS. 5A and 5B, respectively, following the removal of sacrificial gates 402 and sacrificial layers 202, according to some embodiments. In examples where gate masking layers are still present, they would be removed at this time. Once sacrificial gates 402 are removed, the fins extending between the corresponding source or drain regions are exposed.

In the example where the fins include alternating semiconductor layers, sacrificial layers 202 are selectively removed to leave behind nanoribbons 602a and 602b that extend between corresponding source or drain regions. For example, nanoribbons 602a extend in the first direction between source or drain regions 502a, and nanoribbons 602b extend in the first direction between source or drain regions 502b. Each vertical (e.g., along the z-direction) set of nanoribbons represents the semiconductor region (or channel region) of a different semiconductor device. Note that the use of the term nanoribbon is not intended to exclude any particular geometries usable for a gate-all-around channel region (such as nanowires). In other embodiments, the nanoribbons of a given device may be a single fin structure, so as to provide a double-gate or tri-gate configuration. In still other embodiments, the nanoribbons of a given channel region may be nanosheets extending laterally from a dielectric wall, so as to provide a forksheet configuration. Sacrificial gates 402 and sacrificial layers 202 may be removed using the same isotropic etching process or different isotropic etching processes.

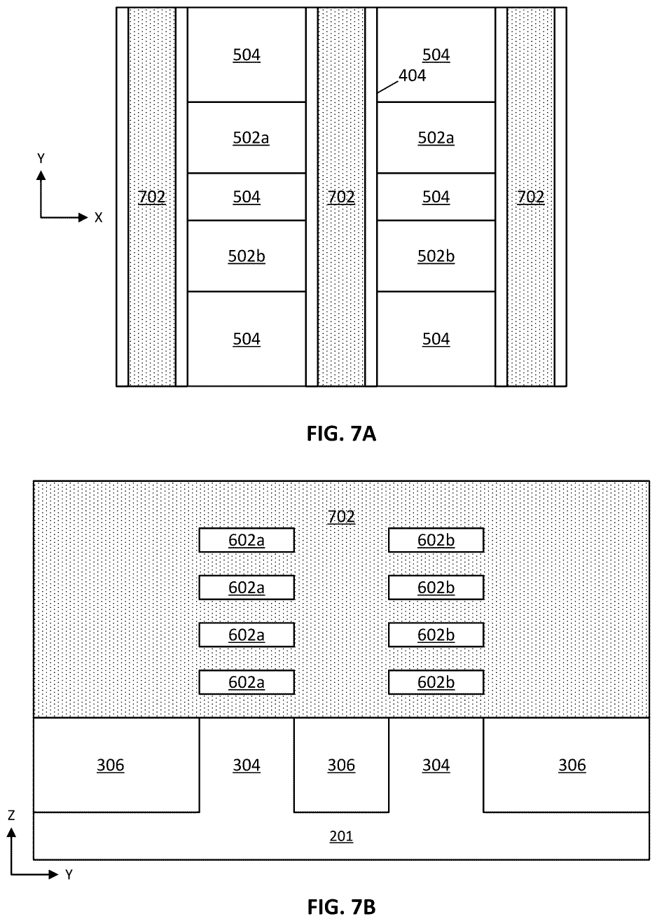

FIGS. 7A and 7B depict plan and cross-section views of the structure shown in FIGS. 6A and 6B, respectively, following the formation of gate structures 702 within the gate trenches between spacer structures 404, according to some embodiments. Gate structures 702 may be formed within the gate trenches over the nanoribbons or fins extending between corresponding source or drain regions. For example, nanoribbons 602a and 602b extend along the first direction beneath gate structures 702 between source or drain regions 502a and 502b, respectively.

Gate structures 702 each include a gate dielectric and a gate electrode. The gate dielectric may be first formed around nanoribbons 602a/602b or fins prior to the formation of the gate electrode, which may include one or more conductive layers. The gate dielectric may include any gate dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric includes a layer of hafnium oxide with a thickness between about 0.5 nm and about 5 nm. In some embodiments, the gate dielectric may include one or more silicates (e.g., titanium silicate, tungsten silicate, niobium silicate, and silicates of other transition metals). In some cases, the gate dielectric includes a first layer on nanoribbons 602a/602b or the fin, and a second layer on the first layer. The first layer can be, for instance, an oxide of the semiconductor material of the nanoribbons 602a/602b or fin (e.g., silicon dioxide) and the second layer can be a high-k dielectric material (e.g., hafnium oxide).

The one or more conductive layers that make up the gate electrode may be deposited using electroplating, electroless plating, CVD, PECVD, ALD, or PVD, to name a few examples. In some embodiments, the gate electrode includes doped polysilicon, a metal, or a metal alloy. Example metals or metal alloys include aluminum, tungsten, cobalt, molybdenum, ruthenium, titanium, tantalum, copper, and carbides and nitrides thereof. The gate electrode may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

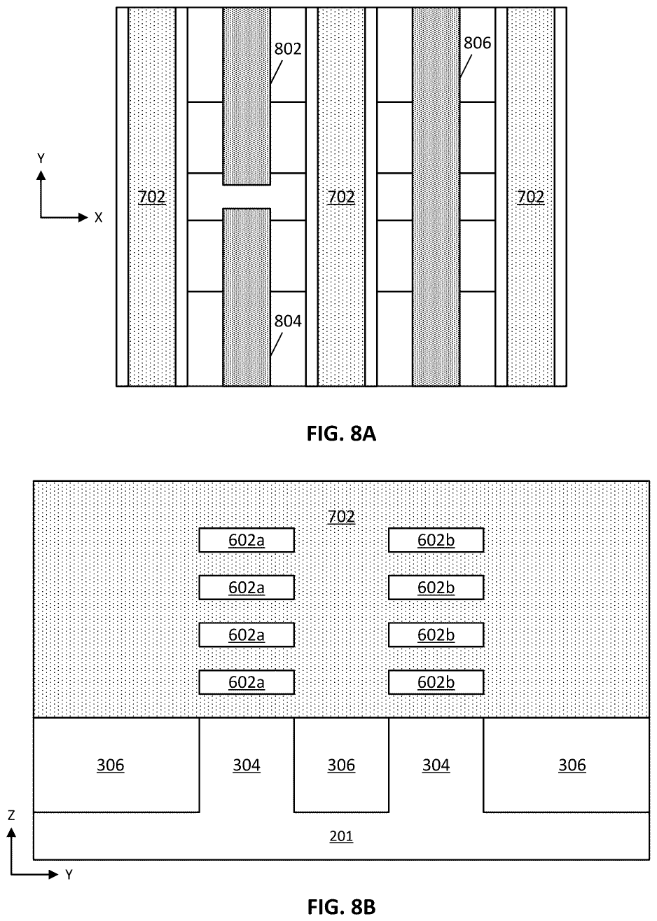

FIGS. 8A and 8B depict plan and cross-section views of the structure shown in FIGS. 7A and 7B, respectively, following the formation of various topside contacts on the top surfaces of the source or drain regions, according to some embodiments. Topside contacts 802, 804, and 806 may include any suitable conductive material, such as tungsten, molybdenum, cobalt, titanium, tantalum, ruthenium, or any alloys thereof, for making electrical contact with the underlying source or drain regions. According to some embodiments, portions of dielectric fill 504 are recessed to expose at least the top surfaces of the source or drain regions, and topside contacts 802, 804, and 806 are formed within the respective recesses using any suitable metal deposition process. According to some embodiments, topside contact 806 may extend along the second direction across the top surfaces of multiple source or drain regions. The top surfaces of topside contacts 802, 804, and 806 may be polished to be substantially coplanar with a top surface of dielectric fill 504 and/or spacer structures 404. It should be understood that topside contacts 802, 804, and 806 may be formed either before or after the formation of gate structures 702. Note that the formation of topside contacts 802, 804, and 806 can also take place downstream in the process flow after the formation of gate cuts and fin cuts.

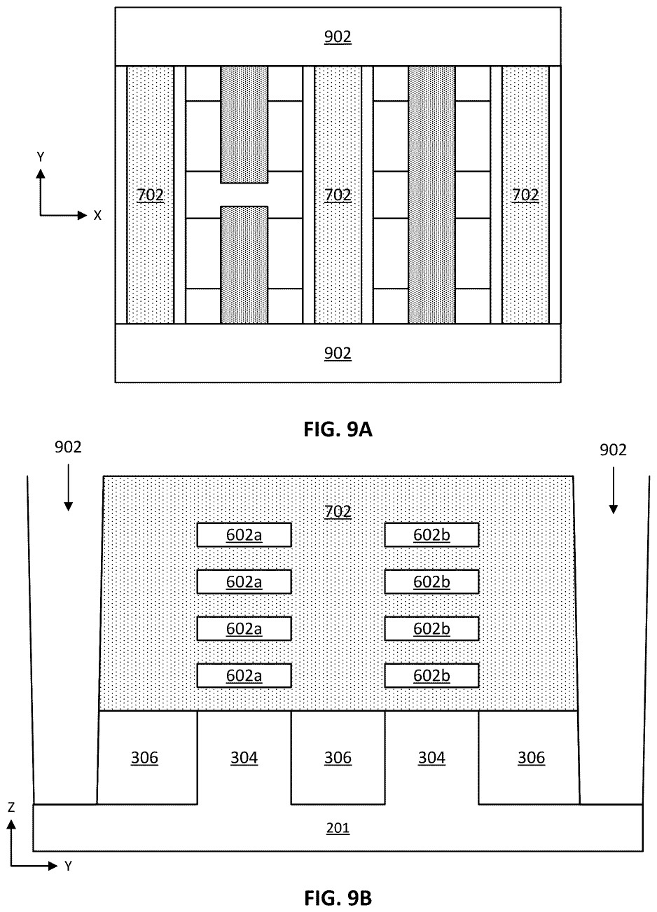

FIGS. 9A and 9B depict plan and cross-section views of the structure shown in FIGS. 8A and 8B, respectively, following the formation of trench recesses 902, according to some embodiments. A RIE process may be used to form trench recesses 902 by etching through at least an entire thickness of gate structure 702 and through at least a portion of dielectric layer 306. In some examples, trench recesses 902 extend through an entire thickness of dielectric layer 306 and may also extend into at least a portion of substrate 201. As seen in FIG. 9A, trench recesses 902 may extend parallel to one another in the first direction (e.g., along boundaries of a standard unit cell). According to some embodiments, trench recesses 902 also cut across any number of different gate structures 702. Due to the relatively high aspect-ratio of trench recesses 902, the sidewalls of trench recesses 902 may taper inwards as illustrated in FIG. 9B.

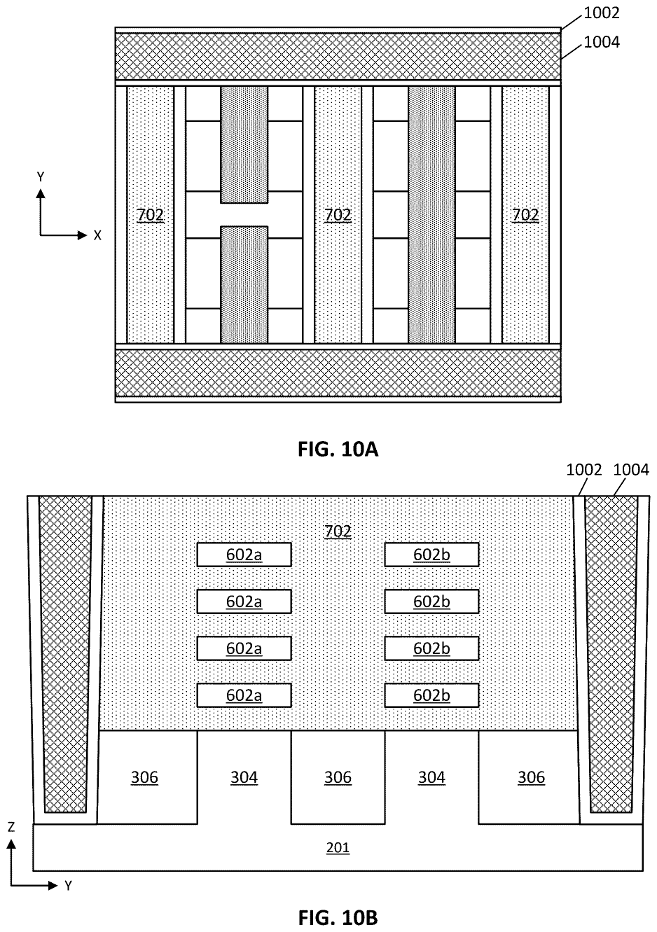

FIGS. 10A and 10B depict plan and cross-section views of the structure shown in FIGS. 9A and 9B, respectively, following the formation of a dielectric liner 1002 and a sacrificial fill 1004 within trench recesses 902, according to some embodiments. Dielectric liner 1002 may be conformally deposited on all exposed surfaces within trench recesses 902 using a suitable deposition technique, such as CVD, ALD, or PECVD. Dielectric liner 1002 may include silicon nitride or silicon oxynitride and have a thickness between about 2 nm and about 10 nm.

Sacrificial fill 1004 may be deposited within the remaining volume of trench recesses 902 following the formation of dielectric liner 1002. According to some embodiments, sacrificial fill 1004 includes a material that can be selectively removed at a later time while causes minimal to no damage to surrounding structures. In some examples, sacrificial fill 1004 includes carbon hard mask (CHM) or a spin-on glass material. Sacrificial fill 1004 may also be deposited over the entire structure outside of trench recesses 902 without any polishing (although this is not shown in the plan view of FIG. 10A for clarity).

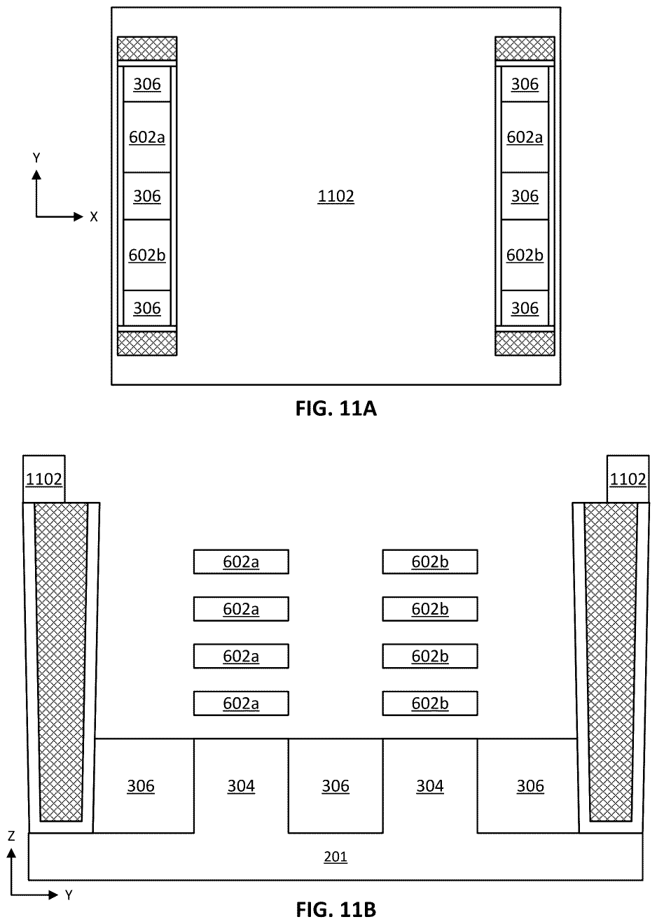

FIGS. 11A and 11B depict plan and cross-section views of the structure shown in FIGS. 10A and 10B, respectively, following the formation of a mask structure 1102 that exposes different gate structures 702 extending in the second direction between the structures formed in trench recesses 902, according to some embodiments. Mask structure 1102 may be any suitable hard mask material any may include any number of material layers. An etching process may then be performed to remove the exposed gate structures, according to some embodiments. As seen in FIG. 11A, mask structure 1102 may protect the majority of the underlying structure, except for one or more of the gate structures, which are removed to expose the semiconductor regions (e.g., nanoribbons 602a and 602b). Any number of isotropic etching processes may be used to remove the conductive materials of the gate electrode followed by the dielectric material(s) of the gate dielectric.

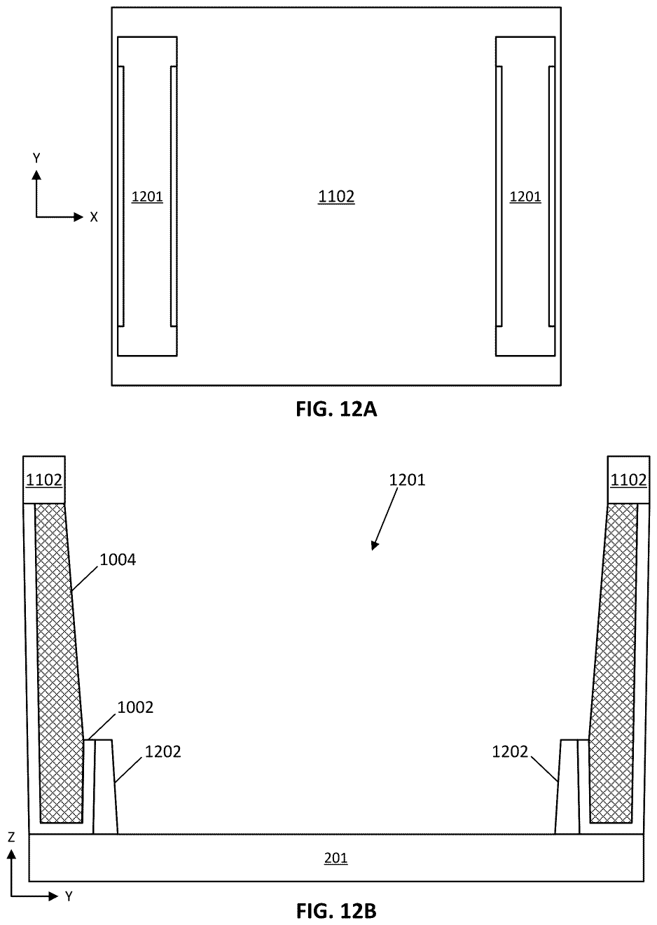

FIGS. 12A and 12B depict plan and cross-section views of the structure shown in FIGS. 11A and 11B, respectively, following one or more anisotropic etching processes to remove at least the exposed nanoribbons 602a/602b, according to some embodiments. One or more RIE processes may be used to remove any exposed portions of nanoribbons 602a/602b. In some examples, the etching process also removes subfin regions 304 as well as portions of the dielectric layer 306 around subfin regions 304 to form trench recesses 1201 that extend along the second direction. According to some embodiments, the etching process(es) also remove exposed portions of dielectric liner 1002 and sacrificial fill 1004. Due to the high aspect ratio nature of the opening, the etch causes the walls of trench recesses 1201 to taper inwards as illustrated in FIG. 12B. This tapering can lead to portions of dielectric layer 306 being left behind as dielectric plugs 1202. According to some embodiments, dielectric plugs 1202 remain at the bottom of trench recesses 1201 directly adjacent to portions of dielectric liner 1002.

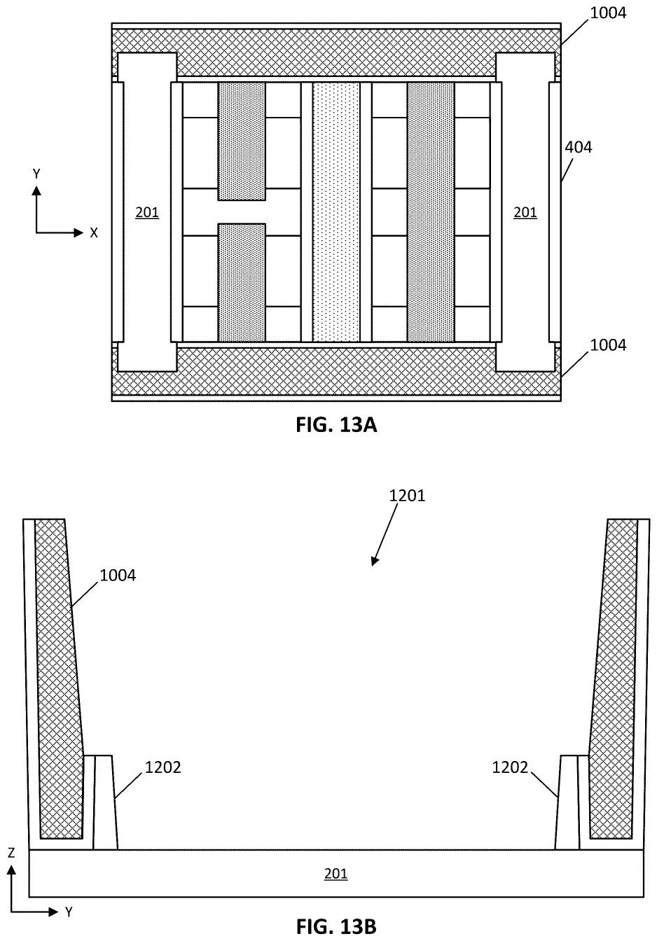

FIGS. 13A and 13B depict plan and cross-section views of the structure shown in FIGS. 12A and 12B, respectively, following the removal of mask structure 1102, according to some embodiments. Trench recesses 1201 can be seen extending in the second direction between parallel structures of sacrificial fill 1004. According to some embodiments, trench recesses 1201 extend into at least a portion of sacrificial fill 1004. Note that spacer structures 404 may remain intact following the formation of trench recesses 1201. In other examples, at least a portion of spacer structures 404 is removed during the etching process(es) used to form trench recesses 1201.

FIGS. 14A and 14B depict plan and cross-section views of the structure shown in FIGS. 13A and 13B, respectively, following the removal of sacrificial fill 1004 and the subsequent formation of a dielectric fill 1402 within both trench recesses 902 and 1201, according to some embodiments. Dielectric fill 1402 may be any suitable dielectric material, such as silicon dioxide or silicon oxynitride. In some examples, dielectric fill 1402 includes a low-k dielectric material and dielectric liner 1002 includes a high-k dielectric material. A single polishing step may be used to planarize a top surface of dielectric fill 1402 to be substantially coplanar with a top surface of spacer structures 404. As can be seen in FIG. 14A, dielectric fill 1402 may extend continuously between gate cuts 1404 (extending in the first direction) and fin cuts 1406 (extending in the second direction).

According to some embodiments, the formation of dielectric fill 1402 in the “cup-like” regions at the bottom of gate cuts 1404 adjacent to fin cuts 1406 can cause a seam 1408 to form within a dielectric core at those bottom portions of gate cuts 1404, as seen in FIG. 14B. Seam 1408 may form from the conformal deposition of dielectric fill 1402 on the inner sidewalls of dielectric liner 1002 at the bottom portions of gate cuts 1404. Seam 1408 may extend along the first direction and join with a longer seam that extends along more of the height of gate cuts 1404 in the regions where gate cuts 1404 do not intersect with fin cuts 1406.

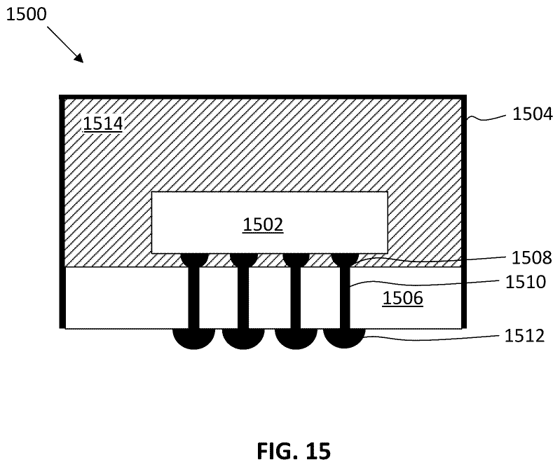

FIG. 15 illustrates an example embodiment of a chip package 1500, in accordance with an embodiment of the present disclosure. As can be seen, chip package 1500 includes one or more dies 1502. One or more dies 1502 may include at least one integrated circuit, such as any of the integrated circuits disclosed herein. One or more dies 1502 may include any other circuitry used to interface with other devices formed on the dies, or other devices connected to chip package 1500, in some example configurations.

As can be further seen, chip package 1500 includes a housing 1504 that is bonded to a package substrate 1506. The housing 1504 may be any standard or proprietary housing, and may provide, for example, electromagnetic shielding and environmental protection for the components of chip package 1500. The one or more dies 1502 may be conductively coupled to a package substrate 1506 using connections 1508, which may be implemented with any number of standard or proprietary connection mechanisms, such as solder bumps, ball grid array (BGA), pins, or wire bonds, to name a few examples. Package substrate 1506 may be any standard or proprietary package substrate, but in some cases includes a dielectric material having conductive pathways (e.g., including conductive vias and lines) extending through the dielectric material between the faces of package substrate 1506, or between different locations on each face. In some embodiments, package substrate 1506 may have a thickness less than 1 millimeter (e.g., between 0.1 millimeters and 0.5 millimeters), although any number of package geometries can be used. Additional conductive contacts 1512 may be disposed at an opposite face of package substrate 1506 for conductively contacting, for instance, a printed circuit board (PCB). One or more vias 1510 extend through a thickness of package substrate 1506 to provide conductive pathways between one or more of connections 1508 to one or more of contacts 1512. Vias 1510 are illustrated as single straight columns through package substrate 1506 for ease of illustration, although other configurations can be used (e.g., damascene, dual damascene, through-silicon via, or an interconnect structure that meanders through the thickness of substrate 1506 to contact one or more intermediate locations therein). In still other embodiments, vias 1510 are fabricated by multiple smaller stacked vias, or are staggered at different locations across package substrate 1506. In the illustrated embodiment, contacts 1512 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1512, to inhibit shorting.

In some embodiments, a mold material 1514 may be disposed around the one or more dies 1502 included within housing 1504 (e.g., between dies 1502 and package substrate 1506 as an underfill material, as well as between dies 1502 and housing 1504 as an overfill material). Although the dimensions and qualities of the mold material 1514 can vary from one embodiment to the next, in some embodiments, a thickness of mold material 1514 is less than 1 millimeter. Example materials that may be used for mold material 1514 include epoxy mold materials, as suitable. In some cases, the mold material 1514 is thermally conductive, in addition to being electrically insulating.

### Methodology

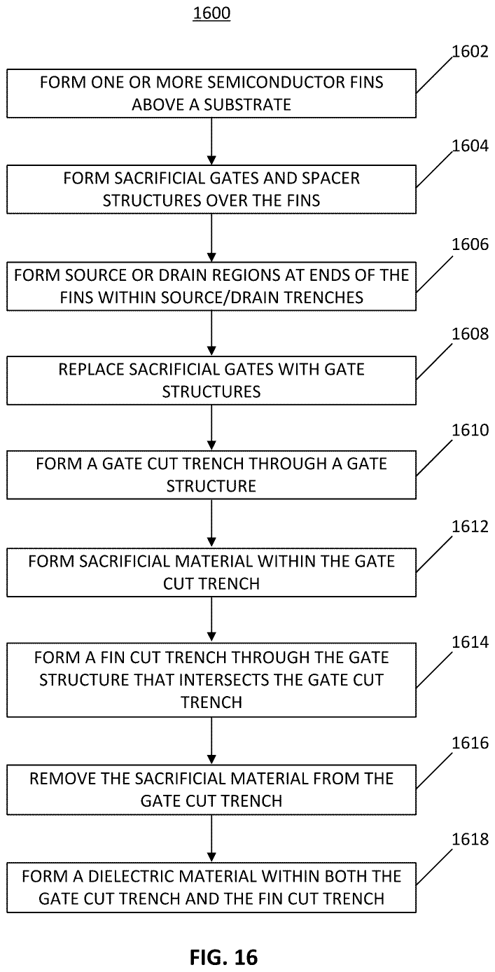

FIG. 16 is a flow chart of a method 1600 for forming at least a portion of an integrated circuit, according to an embodiment. Various operations of method 1600 may be illustrated in FIG. 2A-14A and 2B-14B. However, the correlation of the various operations of method 1600 to the specific components illustrated in the aforementioned figures is not intended to imply any structural and/or use limitations. Rather, the aforementioned figures provide one example embodiment of method 1600. Other operations may be performed before, during, or after any of the operations of method 1600. For example, method 1600 does not explicitly describe all processes that are performed to form common transistor structures. Some of the operations of method 1600 may be performed in a different order than the illustrated order.

Method 1600 begins with operation 1602 where any number of parallel semiconductor fins are formed, such as first and second fins, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric layer is formed around subfin portions of each of the first and second fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 1600 continues with operation 1604 where sacrificial gates and spacer structures are formed over the fins. The sacrificial gates may be patterned using gate masking layers in strips that run orthogonally over the fins (e.g., forming a cross-hatch pattern with the fins). The gate masking layers may be any suitable hard mask material, such as carbon hard mask (CHM) or silicon nitride. The sacrificial gates may be formed from any suitable material that can be selectively removed at a later time without damaging the semiconductor material of the fins. In one example, the sacrificial gates include polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 1600 continues with operation 1606 where source/drain trenches are etched through exposed portions of the semiconductor fins. The exposed fin portions not protected beneath the sacrificial gates (and any spacer structures on the sides of the sacrificial gates) may be removed using any anisotropic etching process, such as reactive ion etching (RIE) or other directional etch process. The removal of the exposed fin portions creates source or drain trenches that alternate with gate trenches (currently filled with the sacrificial gates) along the first direction, according to some embodiments. In some embodiments, at least a portion of the subfin regions is also removed such that a top surface of the subfin regions is recessed below a top surface of the adjacent dielectric layer.

According to some embodiments, source or drain regions are formed at the ends of the semiconductor regions. The source or drain regions may be epitaxially grown from the exposed ends of the semiconductor layers within the source/drain trenches. In some example embodiments, the source or drain regions are n-type source or drain regions (e.g., epitaxial silicon) doped with n-type dopants or p-type source or drain regions (e.g., epitaxial SiGe) doped with p-type dopants. According to some embodiments, the first fin includes n-type source or drain regions (in order to form an NMOS device), and the second fin includes p-type source or drain regions (in order to form a PMOS device).

Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 1600 continues with operation 1608 where the sacrificial gates are removed. The sacrificial gates may be removed using an isotropic etching process that selectively removes all of the material from the sacrificial gates, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

According to some embodiments, gate structures are formed in place of the sacrificial gates around the semiconductor regions of the first and second fins within the gate trench. The gate structures may include both a gate dielectric and a gate electrode. The gate dielectric is first formed over the exposed semiconductor regions between the spacer structures followed by forming the gate electrode within the remainder of the gate trench, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples. The gate electrode may include one or more workfunction layers that differ between NMOS and PMOS devices.

Method 1600 continues with operation 1610 where a gate cut trench is formed through at least an entire thickness of the gate structures. According to some embodiments, the gate cut trench extends along the first direction through any number of gate structures to isolate portions of the gate structures on either side of the gate cut trench. One or more anisotropic etching processes (RIE) may be used to form the gate cut trench. In some examples, the gate cut trench extends through at least a portion of the dielectric layer beneath the gate structures. In some examples, the gate cut trench extends into at least a portion of the substrate. Any number of parallel gate cut trenches may be formed. Due to the high aspect ratio nature of the trench, the gate cut trench may have sidewalls that taper inwards.

Method 1600 continues with operation 1612 where a sacrificial material is formed within the gate cut trench. According to some embodiments, a liner is first formed on all exposed surfaces within the gate cut trench followed by filling any remaining volume of the trench with the sacrificial material. The liner may include silicon nitride, or any other suitable high-k dielectric material. The sacrificial material may be CHM or spin-on glass. In some embodiments, the sacrificial material is not polished following its deposition such that it extends up and out of the gate cut trench.

Method 1600 continues with operation 1614 where a fin cut trench is formed through one of the gate structures and intersecting with the gate cut trench. According to some embodiments, the fin cut trench extends along a second direction that is substantially orthogonal to the first direction. The fin cut trench extends through at least an entire thickness of one of the gate structures and also cuts into at least a portion of the sacrificial material within the gate cut trench. In some embodiments, the fin cut trench is formed through a series of isotropic and/or anisotropic etches to remove various materials within the gate trench, including metal materials, semiconductor materials, and dielectric materials. During the etching process(es) at least a portion of the liner exposed within the fin cut trench is also removed, such that the fin cut trench exposes a side of at least a portion of the sacrificial material in the gate cut trench.

Method 1600 continues with operation 1616 where the sacrificial material is removed from the gate cut trench. According to some embodiments, any suitable isotropic etching process is used to remove the sacrificial material. In this way, the sacrificial material is removed from the gate cut trench while removing little to none of the liner within the gate cut trench.

Method 1600 continues with operation 1618 where a dielectric material is deposited or otherwise formed within both the gate cut trench and the fin cut trench at the same time. According to some embodiments, the dielectric material continuously extends between both the gate cut trench and intersecting fin cut trench to complete the formation of both the gate cut and the fin cut. Given the simultaneous deposition of the dielectric material into both the gate cut and fin cut trenches, a continuous body of the dielectric material at least partially occupies both the gate cut and fin cut trenches, such that there is no seam or other evidence of separate (non-contemporaneous) depositions between gate cut and fin cut portions of the overall gate/fin cut structure. In some examples, a liner or barrier layer or the like may be deposited (conformally along the collective walls of the gate and fin cuts that define the overall perimeter of the resulting combinational gate cut/fin cut dielectric structure), prior to deposition of the dielectric material. A single polishing procedure using, for example, CMP may be used to polish the top surface of the dielectric material (and any excess liner/barrier layer material, if present) to planarize both the gate cut and fin cut structures at the same time. The dielectric material may be any suitable dielectric, such as silicon dioxide or generally any low-k dielectric material (e.g., porous silicon dioxide). The liner or barrier layer, if present, may be, for example, tantalum nitride or titanium nitride or titanium or tantalum or silicon nitride or silicon oxynitride or a high-k dielectric material, or other liner/barrier layer material.

### Example System

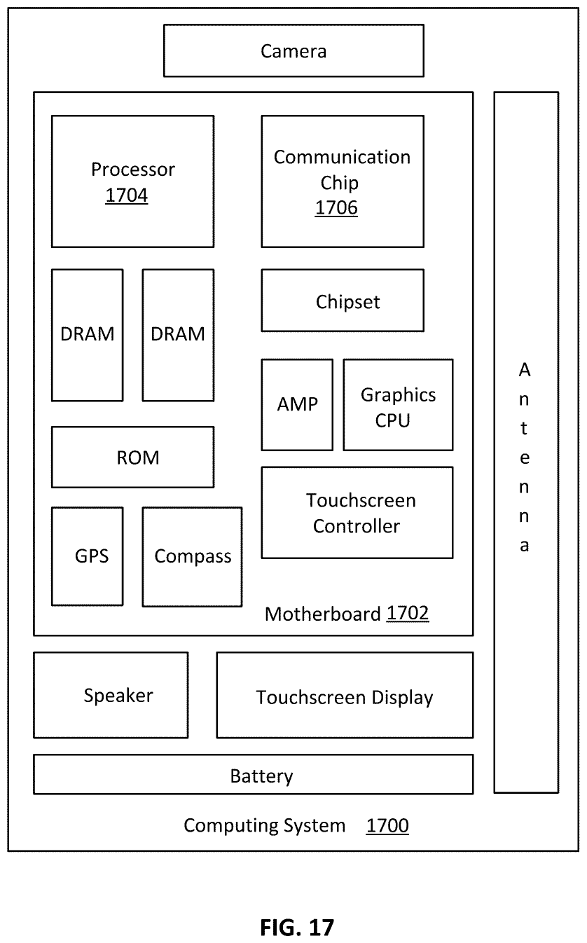

FIG. 17 is an example computing system implemented with one or more of the integrated circuit structures as disclosed herein, in accordance with some embodiments of the present disclosure. As can be seen, the computing system 1700 houses a motherboard 1702. The motherboard 1702 may include a number of components, including, but not limited to, a processor 1704 and at least one communication chip 1706, each of which can be physically and electrically coupled to the motherboard 1702, or otherwise integrated therein. As will be appreciated, the motherboard 1702 may be, for example, any printed circuit board (PCB), whether a main board, a daughterboard mounted on a main board, or the only board of system 1700, etc.

Depending on its applications, computing system 1700 may include one or more other components that may or may not be physically and electrically coupled to the motherboard 1702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1700 may include one or more integrated circuit structures or devices configured in accordance with an example embodiment (e.g., a module including one or more semiconductor devices that include one or more gate cut structures merged with one or more fin cut structures). In some embodiments, multiple functions can be integrated into one or more chips (e.g., for instance, note that the communication chip 1706 can be part of or otherwise integrated into the processor 1704).

The communication chip 1706 enables wireless communications for the transfer of data to and from the computing system 1700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1700 may include a plurality of communication chips 1706. For instance, a first communication chip 1706 may be dedicated to shorter range wireless communications such as Wi-Fi and Bluetooth and a second communication chip 1706 may be dedicated to longer range wireless communications such as GPS, EDGE, GPRS, CDMA, WiMAX, LTE, Ev-DO, and others.

The processor 1704 of the computing system 1700 includes an integrated circuit die packaged within the processor 1704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1706 also may include an integrated circuit die packaged within the communication chip 1706. In accordance with some such example embodiments, the integrated circuit die of the communication chip includes one or more semiconductor devices as variously described herein. As will be appreciated in light of this disclosure, note that multi-standard wireless capability may be integrated directly into the processor 1704 (e.g., where functionality of any chips 1706 is integrated into processor 1704, rather than having separate communication chips). Further note that processor 1704 may be a chip set having such wireless capability. In short, any number of processor 1704 and/or communication chips 1706 can be used. Likewise, any one chip or chip set can have multiple functions integrated therein.

In various implementations, the computing system 1700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1700 may be combined or integrated in a system-on-a-chip (SoC) architecture. In some embodiments, the components may be hardware components, firmware components, software components or any suitable combination of hardware, firmware or software.

### FURTHER EXAMPLE EMBODIMENTS

The following examples pertain to further embodiments, from which numerous permutations and configurations will be apparent.

Example 1 is an integrated circuit that includes a semiconductor region extending from a source or drain region in a first direction, a gate structure extending over the semiconductor region in a second direction substantially orthogonal to the first direction, a first dielectric structure extending along the first direction and crossing the gate structure such that the first dielectric structure extends through at least an entire thickness of the gate structure, and a second dielectric structure extending along the second direction parallel to the gate structure and intersecting the first dielectric structure. The first dielectric structure and the second dielectric structure share a same continuous dielectric material.

Example 2 includes the integrated circuit of Example 1, wherein the first dielectric structure includes a seam at a bottom portion of the first dielectric structure adjacent to the second dielectric structure along the second direction.

Example 3 includes the integrated circuit of Example 2, further comprising a dielectric plug directly between the bottom portion of the first dielectric structure and the adjacent second dielectric structure along the second direction.

Example 4 includes the integrated circuit of Example 2 or 3, wherein the bottom portion of the first dielectric structure includes a dielectric liner on a dielectric core.

Example 5 includes the integrated circuit of Example 4, wherein the dielectric liner comprises a high-k dielectric material and the dielectric core comprises a low-k dielectric material.

Example 6 includes the integrated circuit of Example 4 or 5, wherein the dielectric liner comprises silicon and nitrogen, and the dielectric core comprises silicon and oxygen.

Example 7 includes the integrated circuit of any one of Examples 1-6, wherein the semiconductor region comprises one or more semiconductor nanoribbons.

Example 8 includes the integrated circuit of Example 7, wherein the one or more semiconductor nanoribbons comprises germanium, silicon, or any combination thereof.

Example 9 includes the integrated circuit of any one of Examples 1-8, further comprising a third dielectric structure extending along the first direction parallel to the first dielectric structure, the third dielectric structure crossing the gate structure such that the third dielectric structure extends through at least an entire thickness of the gate structure.

Example 10 includes the integrated circuit of Example 9, wherein the second dielectric structure intersects the third dielectric structure, and wherein the third dielectric structure and the second dielectric structure share the same continuous dielectric material.

Example 11 is a die that includes the integrated circuit of any one of Examples 1-10.

Example 12 is an electronic device that includes a chip package having one or more dies. At least one of the one or more dies includes a semiconductor device having a semiconductor region extending from a source or drain region in a first direction, and a gate structure extending over the semiconductor region in a second direction substantially orthogonal to the first direction, a first dielectric structure extending along the first direction and crossing the gate structure such that the first dielectric structure extends through at least an entire thickness of the gate structure, a second dielectric structure extending along the first direction and crossing the gate structure such that the second dielectric structure extends through at least an entire thickness of the gate structure, and a third dielectric structure extending along the second direction parallel to the gate structure and intersecting the first dielectric structure and the second dielectric structure. The first dielectric structure, the second dielectric structure, and the third dielectric structure share a same continuous dielectric material.

Example 13 includes the electronic device of Example 12, wherein the first dielectric structure includes a seam at a bottom portion of the first dielectric structure adjacent to the third dielectric structure along the second direction, and the second dielectric structure includes a seam at a bottom portion of the second dielectric structure adjacent to the third dielectric structure along the second direction.

Example 14 includes the electronic device of Example 13, wherein the at least one of the one or more dies further comprises: a first dielectric plug directly between the bottom portion of the first dielectric structure and the adjacent third dielectric structure along the second direction; and a second dielectric plug directly between the bottom portion of the second dielectric structure and the adjacent third dielectric structure along the second direction.

Example 15 includes the electronic device of Example 13 or 14, wherein each of the bottom portion of the first dielectric structure and the bottom portion of the second dielectric structure includes a dielectric liner on a dielectric core.

Example 16 includes the electronic device of Example 15, wherein the dielectric liner comprises a high-k dielectric material and the dielectric core comprises a low-k dielectric material.

Example 17 includes the electronic device of Example 15 or 16, wherein the dielectric liner comprises silicon and nitrogen, and the dielectric core comprises silicon and oxygen.

Example 18 includes the electronic device of any one of Examples 12-17, wherein the semiconductor region comprises one or more semiconductor nanoribbons.

Example 19 includes the electronic device of Example 18, wherein the one or more semiconductor nanoribbons comprises germanium, silicon, or any combination thereof.

Example 20 includes the electronic device of any one of Examples 12-19, further comprising a printed circuit board, wherein the chip package is attached to the printed circuit board.

Example 21 is a method of forming an integrated circuit. The method includes forming a fin comprising semiconductor material, the fin extending above a substrate and extending lengthwise in a first direction; forming a first sacrificial gate and a second sacrificial gate each extending in a second direction over the semiconductor material of the fin; forming spacer structures on sidewalls of the first and second sacrificial gates; etching through exposed portions of the fin not protected by the first and second sacrificial gates and spacer structures; forming source or drain regions at exposed ends of the fin; replacing the first sacrificial gate with a first gate structure and the second sacrificial gate with a second gate structure; etching a first trench recess extending in the first direction across both the first gate structure and the second gate structure and through an entire thickness of each of the first gate structure and the second gate structure; forming a sacrificial material within the first trench recess; etching a second trench recess extending in the second direction through the second gate structure and through an entire thickness of the second gate structure, wherein the second trench recess exposes at least a portion of the sacrificial material; removing the sacrificial material; and forming one or more dielectric materials in both the first trench recess and the second trench recess.

Example 22 includes the method of Example 21, further comprising forming a dielectric liner within the first trench recess prior to forming the sacrificial material.

Example 23 includes the method of Example 21 or 22, wherein forming the sacrificial material comprises forming a carbon hard mask (CHM) within the first trench recess.

Example 24 includes the method of any one of Examples 21-23, further comprising polishing a top surface of the one or more dielectric materials in both the first trench recess and the second trench recess using a single polishing operation.

Example 25 is an integrated circuit that includes a semiconductor region extending from a first source or drain region in a first direction, a gate structure extending over the semiconductor region in a second direction substantially orthogonal to the first direction, and a dielectric structure. The dielectric structure has a first section that extends along the first direction and crosses the gate structure such that the first section of the dielectric structure extends through at least an entire thickness of the gate structure and has a second section that extends along the second direction parallel to the gate structure and intersects the first section of the dielectric structure. The dielectric structure comprises a dielectric material that seamlessly extends between the first section and the second section.

Example 26 includes the integrated circuit of Example 25, wherein the first section of the dielectric structure includes a seam at a bottom portion of the first section adjacent to the second section of the dielectric structure along the second direction.

Example 27 includes the integrated circuit of Example 26, further comprising a dielectric plug directly between the bottom portion of the first section and the adjacent second section along the second direction.

Example 28 includes the integrated circuit of Example 26 or 27, wherein the bottom portion of the first section includes a dielectric liner on a dielectric core.

Example 29 includes the integrated circuit of Example 28, wherein the dielectric liner comprises a high-k dielectric material and the dielectric core comprises a low-k dielectric material.

Example 30 includes the integrated circuit of Example 28 or 29, wherein the dielectric liner comprises silicon and nitrogen, and the dielectric core comprises silicon and oxygen.

Example 31 includes the integrated circuit of any one of Examples 25-30, wherein the semiconductor region comprises one or more semiconductor nanoribbons.

Example 32 includes the integrated circuit of Example 31, wherein the one or more semiconductor nanoribbons comprises germanium, silicon, or any combination thereof.

Example 33 includes the integrated circuit of any one of Examples 25-32, wherein the dielectric structure further comprises a third section that extends along the first direction parallel to the first section, the third section crossing the gate structure such that the third section extends through at least an entire thickness of the gate structure.

Example 34 includes the integrated circuit of Example 33, wherein the second section intersects the third section, and wherein the dielectric material seamlessly extends between the third section and the second section.

Example 35 is a die that includes the integrated circuit of any one of Examples 25-34.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor region extending from a source or drain region in a first direction;
a gate structure extending over the semiconductor region in a second direction substantially orthogonal to the first direction;
a first dielectric structure extending along the first direction and crossing the gate structure such that the first dielectric structure extends through at least an entire thickness of the gate structure; and
a second dielectric structure extending along the second direction parallel to the gate structure and intersecting the first dielectric structure, wherein the first dielectric structure and the second dielectric structure share a same continuous dielectric material.

2. The integrated circuit of claim 1, wherein the first dielectric structure includes a seam at a bottom portion of the first dielectric structure adjacent to the second dielectric structure along the second direction.

3. The integrated circuit of claim 2, further comprising a dielectric plug directly between the bottom portion of the first dielectric structure and the adjacent second dielectric structure along the second direction.

4. The integrated circuit of claim 2, wherein the bottom portion of the first dielectric structure includes a dielectric liner on a dielectric core.

5. The integrated circuit of claim 4, wherein the dielectric liner comprises a high-k dielectric material and the dielectric core comprises a low-k dielectric material.

6. The integrated circuit of claim 1, further comprising a third dielectric structure extending along the first direction parallel to the first dielectric structure, the third dielectric structure crossing the gate structure such that the third dielectric structure extends through at least an entire thickness of the gate structure.

7. The integrated circuit of claim 6, wherein the second dielectric structure intersects the third dielectric structure, and wherein the third dielectric structure and the second dielectric structure share the same continuous dielectric material.

8. An electronic device, comprising:
a chip package comprising one or more dies, at least one of the one or more dies comprising
a semiconductor device comprising a semiconductor region extending from a source or drain region in a first direction, and a gate structure extending over the semiconductor region in a second direction substantially orthogonal to the first direction;
a first dielectric structure extending along the first direction and crossing the gate structure such that the first dielectric structure extends through at least an entire thickness of the gate structure;
a second dielectric structure extending along the first direction and crossing the gate structure such that the second dielectric structure extends through at least an entire thickness of the gate structure; and
a third dielectric structure extending along the second direction parallel to the gate structure and intersecting the first dielectric structure and the second dielectric structure, wherein the first dielectric structure, the second dielectric structure, and the third dielectric structure share a same continuous dielectric material.

9. The electronic device of claim 8, wherein the first dielectric structure includes a seam at a bottom portion of the first dielectric structure adjacent to the third dielectric structure along the second direction, and the second dielectric structure includes a seam at a bottom portion of the second dielectric structure adjacent to the third dielectric structure along the second direction.

10. The electronic device of claim 9, wherein the at least one of the one or more dies further comprises:
a first dielectric plug directly between the bottom portion of the first dielectric structure and the adjacent third dielectric structure along the second direction; and
a second dielectric plug directly between the bottom portion of the second dielectric structure and the adjacent third dielectric structure along the second direction.

11. The electronic device of claim 9, wherein each of the bottom portion of the first dielectric structure and the bottom portion of the second dielectric structure includes a dielectric liner on a dielectric core.

12. The electronic device of claim 8, further comprising a printed circuit board, wherein the chip package is attached to the printed circuit board.

13. An integrated circuit comprising:
a semiconductor region extending from a first source or drain region in a first direction;
a gate structure extending over the semiconductor region in a second direction substantially orthogonal to the first direction; and
a dielectric structure comprising
a first section that extends along the first direction and crosses the gate structure such that the first section of the dielectric structure extends through at least an entire thickness of the gate structure, and
a second section that extends along the second direction parallel to the gate structure and intersects the first section of the dielectric structure, wherein the dielectric structure comprises a dielectric material that seamlessly extends between the first section and the second section.

14. The integrated circuit of claim 13, wherein the first section of the dielectric structure includes a seam at a bottom portion of the first section adjacent to the second section of the dielectric structure along the second direction.

15. The integrated circuit of claim 14, further comprising a dielectric plug directly between the bottom portion of the first section and the adjacent second section along the second direction.

16. The integrated circuit of claim 14, wherein the bottom portion of the first section includes a dielectric liner on a dielectric core.

17. The integrated circuit of claim 16, wherein the dielectric liner comprises a high-k dielectric material and the dielectric core comprises a low-k dielectric material.

18. The integrated circuit of claim 13, wherein the dielectric structure further comprises a third section that extends along the first direction parallel to the first section, the third section crossing the gate structure such that the third section extends through at least an entire thickness of the gate structure.

19. The integrated circuit of claim 18, wherein the second section intersects the third section, and wherein the dielectric material seamlessly extends between the third section and the second section.

20. A die comprising the integrated circuit of claim 13.
